(19) United States
(12) Patent Application Publication
(10) Pub. No.: US 2013/0003316 A1
(43) Pub. Date: Jan. 3, 2013

(54) Card Lock Retainer For Pluggable Conduction Cooled Circuit Card Assemblies

(75) Inventor: Robert Alan Martin, San Jose, CA (US)

(73) Assignee: ELMA ELECTRONIC INC., Fremont, CA (US)

(21) Appl. No.: 13/338,135

(22) Filed: Dec. 27, 2011

Related U.S. Application Data
(60) Provisional application No. 61/460,203, filed on Dec. 28, 2010.

(51) Int. Cl. F28F 9/007; H05K 7/20

(52) U.S. Cl. 361/720; 165/67

(57) ABSTRACT

A system is disclosed for releasably locking a circuit card assembly to a cold plate of a chassis. The system includes a locking mechanism having a base and a locking wedge. The base and locking wedge have triangular cross-sections, and mate with each other along respective diagonal surfaces of the base and locking wedge. The locking wedge is mounted to the base such that axial movement of the locking wedge relative to the base also results in sliding of the locking wedge up the diagonal surface of the base to increase the overall height of the base and locking wedge together.

### PRIORITY DATA

The present application claims priority to U.S. Provisional Patent Application No. 61/460,203, by Robert Alan Martin, entitled CARD LOCK RETAINER FOR PLUGGABLE CONDUCTION COOLED CIRCUIT CARD ASSEMBLIES, filed Dec. 28, 2010, which application is incorporated by reference herein in its entirety.

### BACKGROUND

For certain micro-computer chassis, conduction cooling is the preferred heat transfer mode in order to maintain the proper temperature of electrical components on the circuit card assembly (CCA). The CCA is designed so that the heat produced by the electrical components on the card is conducted to the card edge. This heat must then be conducted to a cold plate, so the heat can be removed from the system. Also, there are operational conditions where the CCA is subjected to high shock and vibration loads; thus, the CCA must be securely held in place so it does not lose contact with the connector on the back plane.

These requirements present several design challenges. A locking device is needed on the card edge so that the CCA can be removed freely, but is locked in place during operation. This locking mechanism must fit within the rectangular volume on the edges of the CCA, as shown in FIG. 1. FIG. 1 shows a CCA 20 and a cold plate 22 at one side of the CCA 20 (there may be a second cold plate 22 at the opposite side of CCA 20 as well). A rectangular volume 24 is defined at the interface between the CCA 20 and cold plate 22 which is available for a locking mechanism.

The heat transfer between the CCA and the cold plate should be maximized in order to minimize the operating temperature of the CCA, which will increase the life of the electrical components on the CCA.

According to specification IEEE standard 1101.2-1992, see FIG. 2, the card lock must be no greater than 12.95 mm in height in its relaxed condition, so that the CCA may be inserted and removed from the chassis. But the locking mechanism must be able to expand to a minimum height of 13.59 mm in order to engage the widest cold plate opening. Thus, the devise must have a minimum expansion capability of 0.64 mm.

### BRIEF DESCRIPTION OF THE DRAWINGS

FIG. 1 is a prior art view of a portion of a card cage including a CCA and cold plate.

FIG. 2 is a prior art view of the standard dimensions of a CCA relative to a cold plate.

FIGS. 3a and 3b are edge and perspective views, respectively of a diagonally split locking mechanism for releasably maintaining a CCA in engagement with the cold plate according to an embodiment of the present disclosure.

FIG. 4a is an edge view of a diagonally split locking mechanism holding a CCA in engagement with the cold plate in an unlocked position according to an embodiment of the present disclosure.

FIG. 4b is an edge view of a diagonally split locking mechanism holding a CCA in engagement with the cold plate in locked position according to an embodiment of the present disclosure.

FIG. 4c shows a pair of enlarged edge views of a diagonally split locking mechanism in the unlocked and locked positions, respectively.

FIG. 5 is a perspective view of a diagonally split locking mechanism according to an embodiment of the present disclosure.

FIG. 5a is an exploded perspective view of a diagonally split locking mechanism according to an embodiment of the present disclosure.

FIG. 6a is an enlarged view of a portion of a diagonally split locking mechanism with a pin in a first position according to embodiments of the present disclosure.

FIG. 6b is an enlarged view of a portion of a diagonally split locking mechanism with a pin in a second position according to embodiments of the present disclosure.

FIG. 7a is a perspective view of a diagonally split locking mechanism in an unlocked position according to embodiments of the present disclosure.

FIG. 7b is a perspective view of a diagonally split locking mechanism in an unlocked position according to embodiments of the present disclosure.

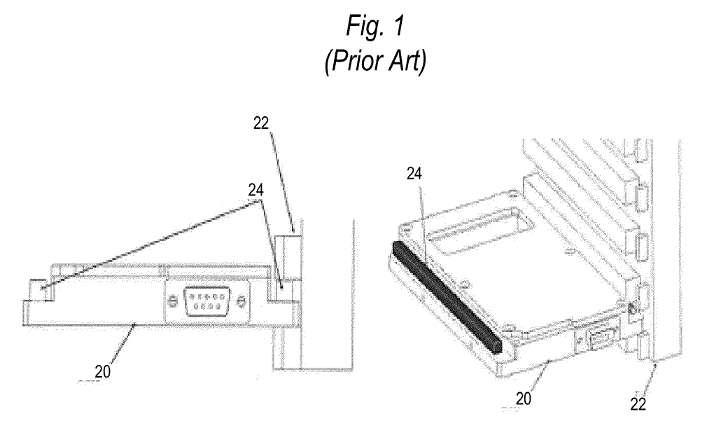

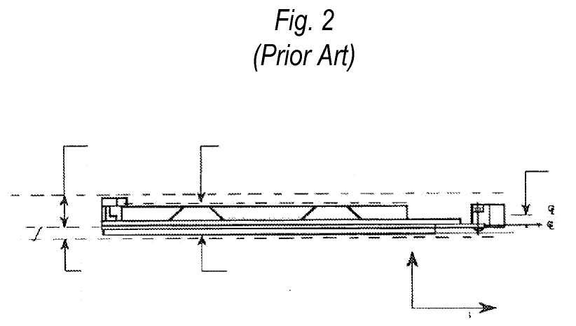

### DETAILED DESCRIPTION

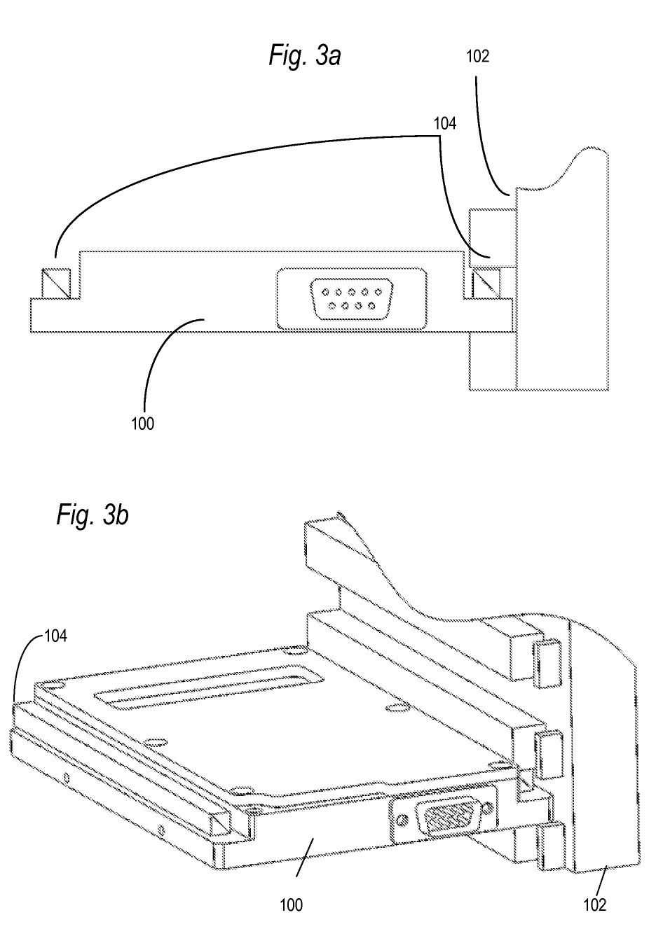

Embodiments of the present disclosure will now be described with reference to FIGS. 3 through 7b, which in general relate to a diagonally split locking mechanism capable of moving between a first position where the locking mechanism allows release of a CCA from a cold plate of a chassis, and a second position where the locking mechanism locks the CCA to the cold plate. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

Embodiments of the present disclosure work on the principle of dividing the rectangular envelope between the cold plate and the CCA into two triangular pieces which run the length of the card. FIGS. 3a and 3b shows a CCA 100 engaged with a cold plate 102, and held therein by a diagonally split locking mechanism (or locking device) 104. As shown, the locking device 104 may be provided at each edge of the CCA 100.

Splitting the volume in this way provides the opportunity for the required expansion of the locking device 104 while maintaining superior contact with the CCA 100. This principle maximizes the contact surface area between the locking mechanism 104 and the cold plate 102. Also, the retainer is nearly a solid mass throughout the contact region once it is in the locked position. This greatly improves the heat conduction capability through the locking mechanism 104.

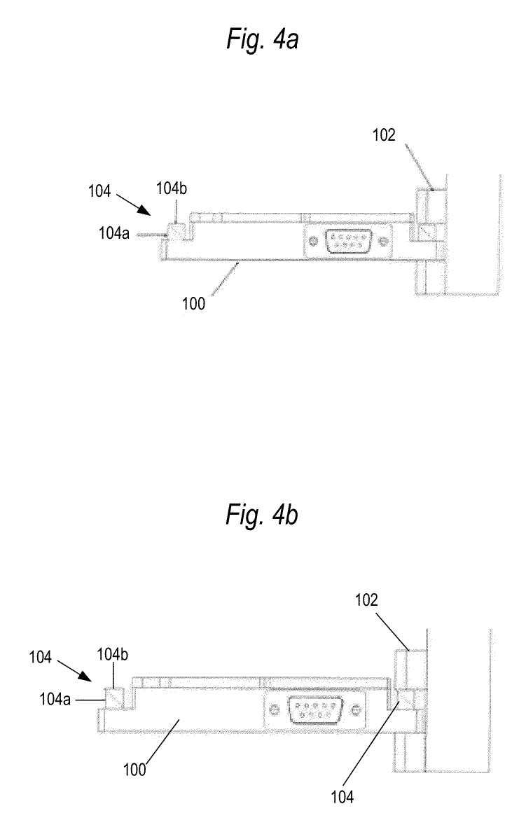

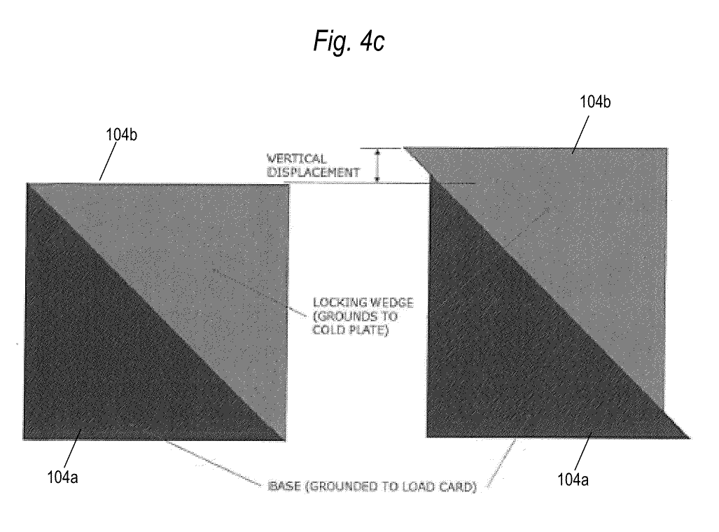

The locking mechanism 104 includes a base 104a and a locking wedge 104b (as seen for example in FIGS. 4a through 7b). The base 104a and locking wedge 104b have triangular shape taken through a cross section perpendicular to the axial length of the locking mechanism 104. The base 104a and locking wedge 104b fit together along generally diagonal surfaces of the base and locking wedge so that a surface of the base engaging the CCA 100 is generally parallel to a surface of the locking wedge capable of engaging an overhanging portion of the cold plate 102. The base 104a of the locking mechanism 104 is fixed to the CCA 100, while the locking wedge 104b is coupled to the base in a way that allows axial movement of the locking wedge 104b relative to the base 104a (movement along the axial length of the base), and upward movement of the locking wedge 104b relative to the base 104a (movement perpendicular to a portion of the CCA 100 on which base 104a is supported). These movements are explained below. FIGS. 4a through 7b show the operating principle of this device. FIG. 4a and the left side drawing of FIG. 4c show the base 104a and locking wedge 104b of the locking mechanism 104 in a first position relative to each other in which the CCA 100 may be removed from the cold plate 102. FIG. 4b and the right side drawing of FIG. 4c show the base 104a and locking wedge 104b of the locking mechanism 104 in a second position relative to each other in which the CCA 100 is locked to the cold plate 102. In the unlocked position of FIG. 4a, the base 104a and locking wedge 104b align with each other in a plane perpendicular to the axis of the locking mechanism 104 so that the overall height of the locking mechanism 104 (i.e., the dimension perpendicular to a portion of the CCA 100 on which base 104a is supported) is at a minimum or near minimum. In the locked position shown in FIG. 4b, the locking wedge 104b has slid up the diagonal between base 104a and locking wedge 104b to increase the overall height of the locking mechanism 104.

This concept presents several practical design challenges. First, a force must be provided by the user who has only access to the front of the devise. That is, the user is only able to pull/push the CCA 100 into or out of the page from the perspective of FIGS. 4a and 4b. This motion has to provide a tangential force to the ramp in order to move the upper locking piece into position. The upper piece and lower piece has to be held together in a way as to allow the relative sliding motion between the two pieces. Finally, there has to be a provision for returning capability, so that the user can unlock the card and remove it.

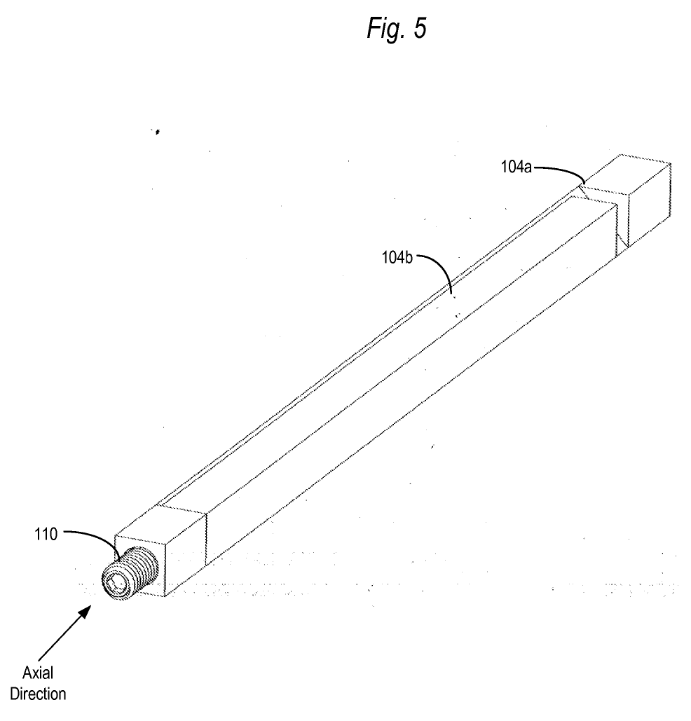

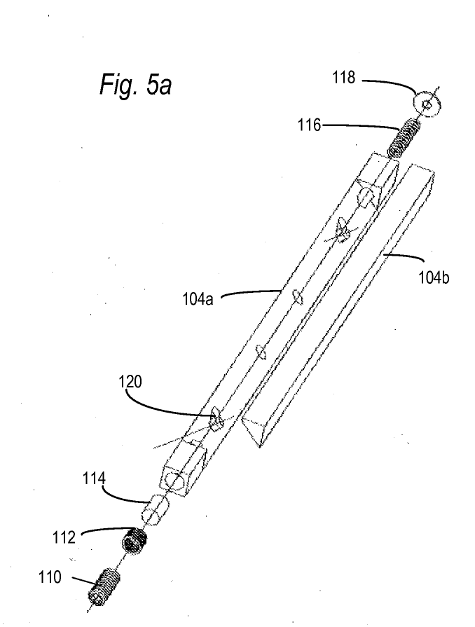

Referring to FIGS. 5 and 5a, the locking wedge 104b begins at it lowered position (aligned in cross-section with the base 104a). Once the CCA 100 is in place, the user turns a set screw 110 in the front of the device. The set screw is threaded through a helicoil 112 mounted through an axial opening at a front portion of base 104a. Upon rotation, the set screw 110 translates laterally relative to the base 104a and pushes the locking wedge 104b axially along the base 104a, by way of a plunger 114 which protects the locking wedge 104b from the rotational action of the screw.

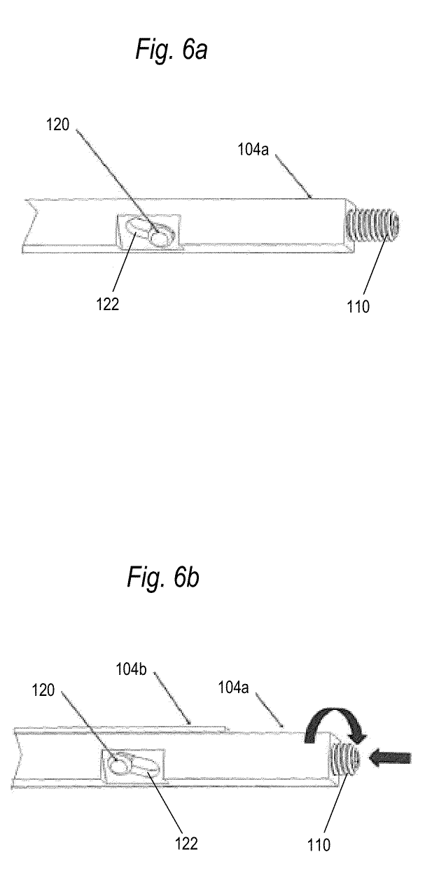

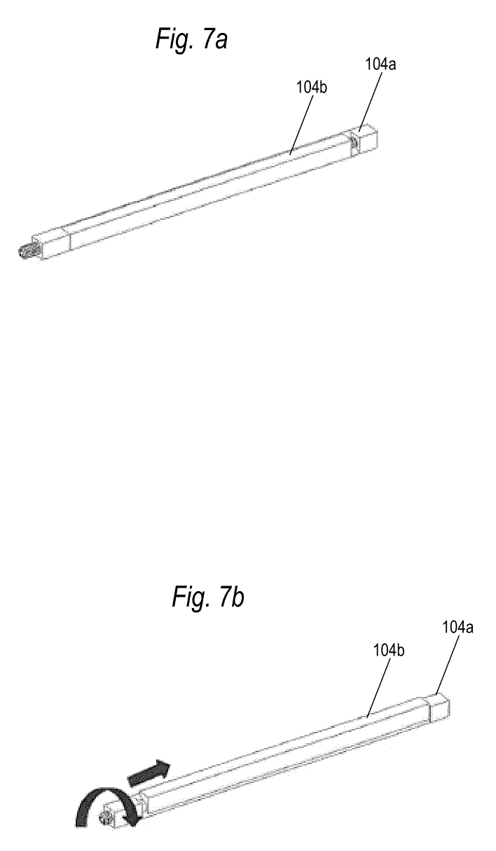

As the locking wedge 104b translates laterally along the base, the input force from the screw has to be redirected upwards. One means is through the use of pins 120 (FIGS. 6a and 6b) which are fixed to, and extend from, the locking wedge 104b. The pins 120 ride within slanted channels 122 formed in the base 104a. When the screw 110 is activated, the pins 120 slide along slanted channels 122 in the base 104a. This pushes the locking wedge 104b upwards along the ramp of the base 104a, until contact is made with an overhanging surface of the cold plate 102. FIGS. 7a and 7b show drawings of the diagonally split locking mechanism 104 in the locked and unlocked condition, respectively. Once the locking wedge 104b makes contact with the cold plate 102, the locking force is determined by the torque applied to the set screw.

When the user wishes to remove the CCA 100 from the computer chassis, the set screw 110 is rotated in the opposite direction than for locking. A compression spring 116 (FIG. 5a) in the rear of the base 104a will push the top locking wedge axially back to the starting position. The compression spring may be held in an axial opening in a rear portion of the base 104a by an end cap 118. Again, while traveling axially back to its starting position, the locking wedge 104a is lowered through the action of the pins 120 traveling in their slanted channels 122. Once the locking wedge 104b is removed from the cold plate 102, the CCA 100 is unlocked and can be removed from the chassis.

In summary, one example of the present disclosure relates to a system for removably securing a circuit card assembly within a space defined by portions of a cold plate of a chassis, comprising: a locking mechanism positioned in the space defined by the portions of the cold plate, the locking mechanism including: a base, and a locking wedge engaged with the base, the base and locking wedge fitting together so that the locking wedge is capable of moving between a first position relative to the base where the locking mechanism does not lock the circuit card assembly to the portions of the cold plate, and a second position relative to the base where the locking mechanism locks the circuit card assembly to the portions of the cold plate.

Another example of the present disclosure relates to a system for removably securing a circuit card assembly within a space defined by portions of a cold plate of a chassis, comprising: a locking mechanism positioned in the space defined by the portions of the cold plate, the locking mechanism including: a base, and a locking wedge engaged with the base, the locking wedge translationally mounted to the base to allow axial movement of the locking wedge relative to the base, and the locking wedge translationally mounted to the base so that an axial movement of the locking wedge relative to the base increases an overall height of the base and locking wedge together.

A still further example of the present disclosure relates to a system for removably securing a circuit card assembly within a space defined by portions of a cold plate of a chassis, comprising: a locking mechanism positioned in the space defined by the portions of the cold plate, the locking mechanism including: a base fixed to the circuit card assembly, the base including a triangular cross-section in a plane perpendicular to an axial length of the base, and a locking wedge including a triangular cross-section in a plane perpendicular to an axial length of the locking wedge, the base and locking wedge mating with each other along diagonal surfaces of the base and locking wedge, the base and locking wedge together having an overall height at least partially filling the space defined by the portions of the cold plate, wherein axial movement of the locking wedge relative to the base biasing the locking wedge in a second direction perpendicular to the axial direction, biasing the locking wedge in the second direction increasing the overall height of the base and locking wedge; and an actuator for translating the locking wedge axially relative to the base.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed:

1. A system for removably securing a circuit card assembly within a space defined by portions of a cold plate of a chassis, comprising:
a locking mechanism positioned in the space defined by the portions of the cold plate, the locking mechanism including:
a base, and
a locking wedge engaged with the base, the base and locking wedge fitting together so that the locking wedge is capable of moving between a first position relative to the base where the locking mechanism does not lock the circuit card assembly to the portions of the cold plate, and a second position relative to the base where the locking mechanism locks the circuit card assembly to the portions of the cold plate.

2. The system of claim 1, wherein the base is fixedly mounted to the circuit card assembly.

3. The system of claim 1, wherein the base and locking wedge have triangular cross sections, with the base engaging the locking wedge along diagonal surfaces of the base and locking wedge.

4. The system of claim 3, wherein the diagonal surface of locking wedge slides along the diagonal surface of the base between the first and second positions of the locking wedge.

5. The system of claim 4, wherein sliding of the locking wedge along the diagonal surface of the base increases a height of the locking mechanism.

6. The system of claim 1, wherein the base and locking wedge both have a solid mass to maximize heat conduction from the circuit card assembly to the cold plate through the locking mechanism.

7. A system for removably securing a circuit card assembly within a space defined by portions of a cold plate of a chassis, comprising:
a locking mechanism positioned in the space defined by the portions of the cold plate, the locking mechanism including:
a base, and
a locking wedge engaged with the base, the locking wedge translationally mounted to the base to allow axial movement of the locking wedge relative to the base, and the locking wedge translationally mounted to the base so that an axial movement of the locking wedge relative to the base increases an overall height of the base and locking wedge together.

8. The system of claim 7, further comprising a set screw affixed through an opening in the base, rotation of the set screw translating the set screw relative to the base, the set screw bearing against the locking wedge upon rotation of the set screw to translate the locking wedge axially relative to the base.

9. The system of claim 8, wherein the base and locking wedge have triangular cross sections, with the base engaging the locking wedge along diagonal surfaces of the base and locking wedge.

10. The system of claim 9, further comprising a pin and channel in the base and locking wedge, the pin riding in the channel, the channel provided at an angle so that axial movement of the locking wedge relative to the base results in locking wedge riding up the diagonal surface of the base to increase the overall height of the base and locking wedge together.

11. The system of claim 10, wherein the pin extends off of the locking wedge into the channel, the channel formed in the base.

12. The system of claim 7, further comprising:
a pin extending from the locking wedge,
a channel formed in the base, the pin riding in the channel, the channel provided at a slant in the base so that, as the pin moves axially with the locking wedge, the pin riding in the slanted channel also moves the locking wedge upward relative to the base to increase the overall height of the base and locking wedge together.

13. The system of claim 12, further comprising a set screw affixed within an opening in the base, rotation of the set screw causing axial translation of the locking wedge relative to the base.

14. The system of claim 13, wherein the set screw may be rotated to a point where the locking wedge is moved upward to engage a portion of the cold plate to thereby lock the locking mechanism and circuit card assembly to the portions of the cold plate.

15. The system of claim 14, wherein, after the locking mechanism is locked to the portions of the cold plate, rotation of the set screw in an opposite direction may move the locking wedge away from an engaged portion of the cold plate to free the locking mechanism and the circuit card assembly from the cold plate.

16. The system of claim 7, wherein the base and locking wedge both have a mass maximizing heat conduction from the circuit card assembly to the cold plate through the locking mechanism.

17. A system for removably securing a circuit card assembly within a space defined by portions of a cold plate of a chassis, comprising:
a locking mechanism positioned in the space defined by the portions of the cold plate, the locking mechanism including:
a base fixed to the circuit card assembly, the base including a triangular cross-section in a plane perpendicular to an axial length of the base, and
a locking wedge including a triangular cross-section in a plane perpendicular to an axial length of the locking wedge, the base and locking wedge mating with each other along diagonal surfaces of the base and locking wedge, the base and locking wedge together having an overall height at least partially filling the space defined by the portions of the cold plate, wherein axial movement of the locking wedge relative to the base biasing the locking wedge in a second direction perpendicular to the axial direction, biasing the locking wedge in the second direction increasing the overall height of the base and locking wedge; and
an actuator for translating the locking wedge axially relative to the base.

18. The system of claim 17, further comprising:
a pin extending from the locking wedge,
a channel formed in the base, the pin riding in the channel, the channel provided at a slant in the base so that, as the pin moves axially with the locking wedge, the pin riding in the slanted channel causes movement of the locking wedge in the second direction.

19. The system of claim 17, wherein the actuator is a set screw fit through an opening in the base and capable of translating the locking wedge relative to the screw upon rotation of the set screw.

20. The system of claim 17, wherein the base and locking wedge both have a mass maximizing heat conduction from the circuit card assembly to the cold plate through the locking mechanism.
